(19) United States
(12) Patent Application Publication
(10) Pub. No.: US 2019/0168515 A1
(43) Pub. Date: Jun. 6, 2019

(54) LIGHT-EMITTING ELEMENT ARRAY, AND LIGHT EXPOSURE HEAD AND IMAGE FORMING APPARATUS USING THE SAME

(71) Applicant: CANON KABUSHIKI KAISHA, Tokyo (JP)

(72) Inventors: Koichiro Nakanishi, Tokyo (JP); Takeshi Uchida, Hiratsuka-shi (JP)

(21) Appl. No.: 16/199,587

(22) Filed: Nov. 26, 2018

(30) Foreign Application Priority Data
Dec. 1, 2017 (JP) 2017-231541

(51) Int. Cl. B41J 2/45; H01L 27/15; H01L 33/00; H01L 33/10; H01L 33/14; H01L 33/20; H01L 33/30

(52) U.S. Cl. CPC B41J 2/45; H01L 27/153; H01L 33/0016; H01L 33/30; H01L 33/14; H01L 33/20; H01L 33/10

(57) ABSTRACT

In a light-emitting element array using light emitting thyristors, a light emitting output of each light emitting thyristor can be increased and a variation in the light emitting output can be suppressed. On a substrate, a thyristor having a mesa structure including a cathode layer, a gate layer, a gate layer, and an anode layer is formed. A contact layer is formed on the anode layer. A current constriction region is formed by a region in which the anode layer is in contact with the contact layer. A minimum distance from the current constriction region to a side surface of the mesa structure is greater than or equal to 4 μm.

### BACKGROUND OF THE INVENTION

### Field of the Invention

The present invention relates to a light-emitting element array used for a light exposure head of an electrophotographic printer.

### Description of the Related Art

In electrophotographic printers, a method in which a photosensitive drum is exposed to light using a light exposure head and a latent image is formed is generally known. The light exposure head includes a light-emitting element array including an array of light-emitting elements disposed in a longitudinal direction of the photosensitive drum, and a rod lens array that focuses light from the light-emitting element array on the photosensitive drum. In this case, the length of the light-emitting element array is determined depending on the width of an image region on the photosensitive drum, and a pitch between light-emitting elements is determined depending on the resolution of the printer. For example, in the case of a printer with a resolution of 1200 dpi, the pitch between pixels is 21.16 μm (three or more decimal places are rounded off). Accordingly, a pitch between the light-emitting elements is also 21.16 μm. The number of components used in the printer using such a light exposure head is less than the number of components used in a laser scanning type printer in which a laser beam is deflected and scanned by a polygon motor. Accordingly, in the printer using the light exposure head, the miniaturization of the apparatus and a reduction in costs can be achieved easily.

Examples of the light-emitting elements constituting the light-emitting element array used for the light exposure head include a light-emitting diode (LED) and a surface-emitting laser (VCSEL). In addition, the light-emitting element array including a self-scanning function using a light emitting thyristor has an advantage that only a small number of wires is required. For this reason, the light-emitting element array is developed as an optical head for a copying machine and the like. A light emitting output from the light emitting thyristor is smaller than a light emitting output from a surface-emitting laser or the like. However, a self-scanning-type light-emitting element array in which a current restricting structure is formed in a light emitting thyristor and a current is focused on a part of a light-emitting layer to increase a light emitting output is discussed in Japanese Patent Application Laid-Open No. 2013-58788 and “DocuCentre SC2020” Fuji Xerox Co., Ltd. Technical Report No. 24, 2015.

It is said that, in a light emitting thyristor having a mesa structure, non-light-emitting recombination on a side surface of the mesa structure is one of the factors that reduce the light emitting efficiency. Japanese Patent Application Laid-Open No. 2013-58788 and “DocuCentre SC2020” Fuji Xerox Co., Ltd. Technical Report No. 24, 2015 discuss a structure in which some layers in a semiconductor layer structure are oxidized from the side surface of the mesa structure and are increased in resistance so as to suppress the non-light-emitting recombination on the side surface of the mesa structure, and a current constriction region is formed in the vicinity of the center of the mesa structure. In addition, “DocuCentre SC2020” Fuji Xerox Co., Ltd. Technical Report No. 24, 2015 describes that a light emitting output that is about three times that of the structure can be obtained.

### SUMMARY OF THE INVENTION

In the light-emitting element array, it is favorable that the variation in the light emitting output of each light-emitting element is small. In particular, in the case of using the light-emitting element array for an image forming apparatus, for example, a variation of 5% or less is favorable.

The present invention is directed to providing a light exposure head and an image forming apparatus which have high reliability and have a configuration in which a light emitting output of each light emitting thyristor is increased in a light-emitting element array using the light emitting thyristor, and a variation in the light emitting output of each light emitting thyristor can be suppressed.

According to a first aspect of the present invention, a light-emitting element array includes a substrate and a plurality of light emitting thyristors disposed in an array on the substrate. The light emitting thyristors each have a semiconductor stacked structure in which a first semiconductor layer having a first conductivity type, a second semiconductor layer having a second conductivity type different from the first conductivity type, a third semiconductor layer having the first conductivity type, and a fourth semiconductor layer having the second conductivity type are stacked in this order from a substrate side. At least a part of the semiconductor stacked structure constitutes a mesa structure. The light emitting thyristors each include a current constriction region. A minimum distance d between a side surface of the mesa structure and the current constriction region in a direction in which the plurality of light emitting thyristors is disposed is greater than or equal to 4 μm as viewed along a stacking direction of the plurality of semiconductor layers.

According to a second aspect of the present invention, a light exposure head includes the light-emitting element array according to the first aspect of the present invention, and an optical system member that collects light emitted from the light-emitting element array.

According to a third aspect of the present invention, an image forming apparatus includes: an image supporting body; a charging unit configured to charge a surface of the image supporting body; a light exposure head configured to expose a surface of the image supporting body to light and form an electrostatic latent image on the surface of the image supporting body, the surface of the image supporting body being charged by the charging unit; a development unit configured to develop the electrostatic latent image formed by the light exposure head; and a transfer unit configured to transfer the image developed by the development unit onto a recording medium. The light exposure head is the light exposure head according to the second aspect of the present invention.

In the present invention, the current constriction region is formed in the light emitting thyristor and the minimum distance d from the current constriction region to the side surface of the mesa structure is greater than or equal to 4 μm. With this configuration, a light emitting loss can be reduced and a region in which the light emitting loss changes sharply can be avoided. Consequently, according to the light-emitting element array of the present invention, it is possible to obtain high reliability in a light exposure head and an image forming apparatus which use the light-emitting element array and have a configuration in which the light emitting output of each light emitting thyristor is increased and a variation in the light emitting output of each light emitting thyristor is reduced.

Further features of the present invention will become apparent from the following description of exemplary embodiments with reference to the attached drawings.

### BRIEF DESCRIPTION OF THE DRAWINGS

FIGS. 1A, 1B and 1C schematically illustrate a configuration of a light-emitting element array according to an exemplary embodiment of the present invention.

FIGS. 2A, 2B, 2C, 2D, 2E and 2F illustrate a production process for the light-emitting element array illustrated in FIGS. 1A, 1B and 1C.

FIGS. 3A, 3B and 3C schematically illustrate a configuration of a light-emitting element array according to another exemplary embodiment of the present invention.

FIG. 4 is an equivalent circuit diagram illustrating a self-scanning-type light emitting circuit of the light-emitting element array according to the present invention.

FIGS. 5A, 5B and 5C illustrate a distribution of gate potentials of the self-scanning-type light emitting circuit illustrated in FIG. 4.

FIG. 6 is a schematic diagram illustrating a drive signal waveform of the self-scanning-type light emitting circuit illustrated in FIG. 4.

FIGS. 7A and 7B schematically illustrate a configuration of a light exposure head according to an exemplary embodiment of the present invention.

FIG. 8 is a sectional view schematically illustrating a configuration of an image forming apparatus according to an exemplary embodiment of the present invention.

FIGS. 9A and 9B respectively illustrate a minimum distance d from a current constriction region to a side surface of a mesa structure and a relationship between a light emitting output and a light emitting loss in the light-emitting element array according to an example of the present invention.

### DESCRIPTION OF THE EMBODIMENTS

Preferred embodiments of the present invention will now be described in detail in accordance with the accompanying drawings.

A light-emitting element array according to the present invention includes a substrate and a plurality of light emitting thyristors disposed in an array on the substrate. Each light emitting thyristor has a semiconductor stacked structure in which a first semiconductor layer having a first conductivity type, a second semiconductor layer having a second conductivity type different from the first conductivity type, a third semiconductor layer having the first conductivity type, and a fourth semiconductor layer having the second conductivity type are stacked in this order from a substrate side. At least a part of the semiconductor stacked structure of each light emitting thyristor constitutes a mesa structure in which each light emitting thyristor includes a current constriction region. Further, according to the present invention, a minimum distance d from a side surface of the mesa structure to the current constriction region is greater than or equal to 4 μm as viewed along a stacking direction of the semiconductor layers in the semiconductor stacked structure.

Exemplary embodiments of the present invention will be described in detail below with reference to the drawings as needed. However, the present invention is not limited to the exemplary embodiments described below. Further, techniques known or publicly known in the technical field can be applied to parts not particularly described below or parts not particularly illustrated in the drawings.

### First Exemplary Embodiment

According to a first exemplary embodiment of the present invention, a contact layer is formed on the fourth semiconductor layer in the semiconductor stacked structure of each thyristor and the current constriction region is defined by a region in which the contact layer is in contact with the fourth semiconductor layer.

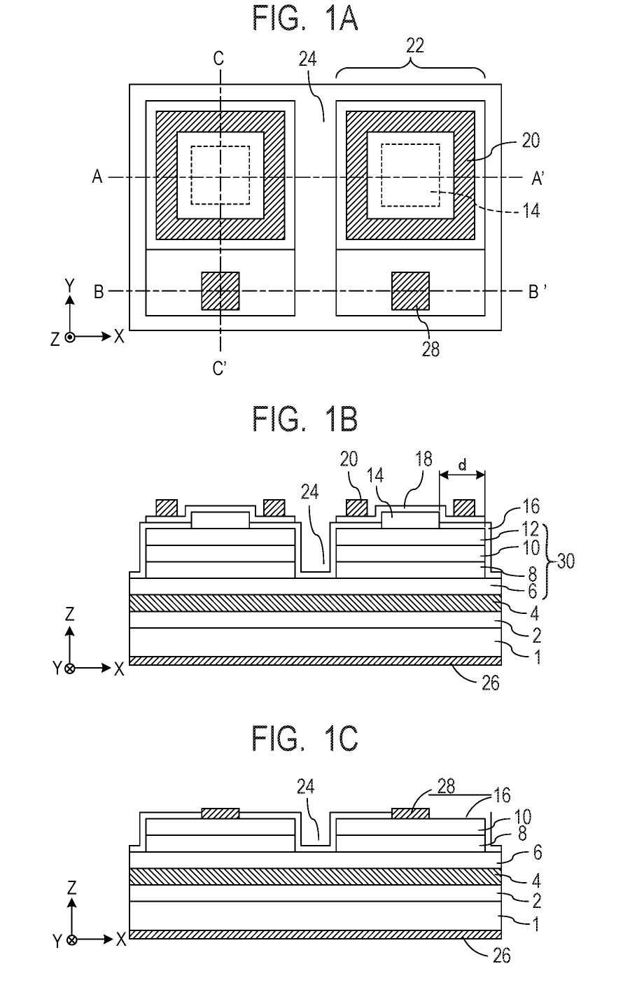

FIGS. 1A to 1C schematically illustrate the configuration according to the present exemplary embodiment, and also illustrate two light emitting thyristors. FIG. 1A is a plan view. FIG. 1B is an end view taken along a line A-A′ in FIG. 1A, and illustrates a sectional structure of an anode portion in each light emitting thyristor. FIG. 1C is an end view taken along a line B-B′ in FIG. 1A, and illustrates a sectional structure of a gate portion in each light emitting thyristor.

Each light emitting thyristor having the mesa structure includes an anode electrode and a gate electrode on the mesa structure. The anode electrode includes an opening. In the present exemplary embodiment, the anode electrode is used as a drive electrode 20 to be described below, and a current constriction region is formed in the opening of the drive electrode 20. A light emitting unit corresponds to a region in which most of a current is mostly concentrated, or a region identical to the current constriction region. In this manner, the current constriction region is formed in the opening of the anode electrode, thereby enabling a reduction in shielding of light emitted from the light emitting unit in the anode electrode and an increase in light emitting output.

As illustrated in FIG. 1A, in the light-emitting element array according to the present invention, light emitting thyristors 22 each having the mesa structure are disposed in an array in an X-direction in FIG. 1A. The present exemplary embodiment illustrates an example where two light emitting thyristors 22 are disposed. The light emitting thyristors 22 each have a semiconductor stacked structure in which a first semiconductor layer having a first conductivity type, a second semiconductor layer having a second conductivity type different from the first conductivity type, a third semiconductor layer having the first conductivity type, and a fourth semiconductor layer having the second conductivity type are stacked in this order from a substrate side. In other words, the light emitting thyristors 22 each have a semiconductor stacked structure in which a plurality of semiconductor layers having different conductivity types are alternately disposed. The present exemplary embodiment includes the semiconductor stacked structure 30 in which, on a substrate 1, a first-conductivity-type cathode layer 6, a second-conductivity-type gate layer 8, a first-conductivity-type gate layer 10, and a second-conductivity-type anode layer 12 are stacked in this order from the substrate 1 side. A semiconductor stacked structure 30 functions substantially as a thyristor. The semiconductor stacked structure 30 is hereinafter referred to as the thyristor 30. One of the first conductivity type and the second conductivity type is an n-type, and the other one of the first conductivity type and the second conductivity type is a p-type. In the present exemplary embodiment, the adjacent light emitting thyristors 22 share the first semiconductor layer, i.e., the cathode layer 6.

As illustrated in FIG. 1B, in the present exemplary embodiment, on the substrate 1, a buffer layer 2, a distributed bragg reflector (DBR) layer 4, and the thyristor 30 are stacked in this order. On the thyristor 30, a contact layer 14 in contact with the anode layer 12 is formed, and an insulating layer 16 is formed in a region other than the contact layer 14. Further, a transparent electrode 18 is formed on the contact layer 14 and on the insulating layer 16 which is formed around the contact layer 14. The drive electrode 20, which is a metal electrode, is formed around the contact layer 14 on the transparent electrode.

In each of the light emitting thyristors 22 having the configuration as described above, the transparent electrode 18 causes a current injected into the drive electrode 20 to extend in directions (X-direction and Y-direction) perpendicular to a stacking direction (Z-direction) of the semiconductor layers of the thyristor 30, and is then injected into the thyristor 30 through the contact layer 14. In this case, since the insulating layer 16 is formed between the anode layer 12 and the transparent electrode 18, the current is intensively injected into the anode layer 12 only from the region in contact with the contact layer 14. In other words, the region in which the anode layer 12 is in contact with the contact layer 14 corresponds to the current constriction region.

As illustrated in FIG. 1C, in the gate portion of each of the light emitting thyristors 22, the anode layer 12 and the contact layer 14 on the gate layer 10 are completely removed, and then a gate electrode 28 is formed on the gate layer 10 and the insulating layer 16 is formed in a region excluding a part of the gate electrode 28.

In the present invention, a minimum distance d between a side surface of the mesa structure and the current constriction region in the direction (X-direction) in which the plurality of light emitting thyristors 22 is disposed as viewed along the stacking direction (Z-direction) of the semiconductor layers of the thyristor 30 is greater than or equal to 4 μm. In the present exemplary embodiment, the current constriction region is a region in which the contact layer 14 and the anode layer 12 are in contact, and the mesa structure includes the gate layer 8, the gate layer 10, and the anode layer 12. Accordingly, as illustrated in FIGS. 1A and 1B, the above-described minimum distance d is a distance parallel to the X-direction from an end of the contact layer 14 to an end of the anode layer 12. In the following description, the above-described minimum distance d is referred to as the side surface distance d.

In the present invention, the side surface distance d is set to be greater than or equal to 4 μm, thereby suppressing a loss of the light emitting output to 20% or less, and also suppressing a variation in the light emitting output to 5% or less. The side surface distance d can be greater than or equal to 5 μm, thereby suppressing a loss of the light emitting output to 10% or less.

The light emitting output is substantially saturated at the side surface distance d of 20 μm, and thus the side surface distance d can be less than or equal to 20 μm. In a case where the density of the light-emitting element array is 600 dpi, the pitch between the light emitting thyristors 22 is 42.2 μm. The width in the column direction of the mesa structure is about 40 μm at maximum, and the side surface distance is about 20 μm at maximum. Accordingly, the side surface distance d can be less than or equal to 20 μm. When the density of the light-emitting element array is 1200 dpi, the pitch between the light emitting thyristors 22 is about 21.1 μm, and thus the side surface distance d can be less than or equal to 10 μm.

Next, a method for producing the light-emitting element array according to the present exemplary embodiment will be described.

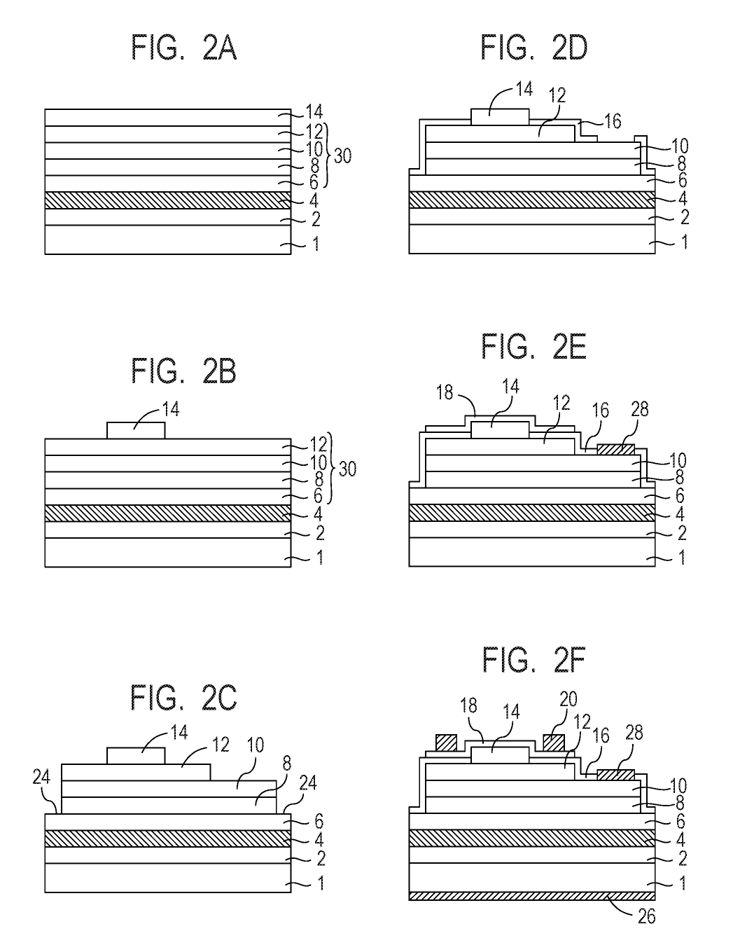

FIGS. 2A to 2F illustrate processes for producing the light-emitting element array illustrated in FIGS. 1A to 1C with reference to an end view taken along a line C-C′ in FIG. 1A.

On the substrate 1, the buffer layer 2 which is formed of semiconductor having the same conductivity type as the conductivity type of the substrate 1 is epitaxially grown. As the substrate 1, an n-type GaAs substrate can be used. A p-type GaAs substrate can also be used. However, higher-quality, lower-cost n-type GaAs substrates are distributed in the market. Therefore, the use of an n-type GaAs substrate makes it possible to obtain a device with an excellent performance at a lower cost, and thus the n-type GaAs substrate is suitably used. As the buffer layer 2, a GaAs layer or AlGaAs layer having the same conductivity type as the conductivity type of the substrate 1 can be used. As the epitaxial growth method, general semiconductor growth methods, such as molecular beam epitaxy and a metalorganic chemical vapor deposition method, can be used.

When n-type semiconductor is used as the substrate 1, the buffer layer 2, the DBR layer 4, the cathode layer 6, and the gate layer 10 are each formed of n-type semiconductor, and the gate layer 8 and the anode layer 12 are each formed of p-type semiconductor.

Next, the DBR layer 4 is stacked. Specifically, for example, AlGaAs having a high Al composition and AlGaAs having a low Al composition can be alternately stacked so that the optical length of each layer is 0.9 to 1.1 times λ/4. In this case, λ represents a wavelength at the center of light emitted from the light emitting thyristors 22. As a combination of the high Al composition and the low Al composition, a combination with a larger difference between the compositions can be used because the combination has a wider reflection bandwidth for the DBR. For example, a combination of an Al composition 0.8 and an Al composition 0.2 and a combination of an Al composition 0.9 and an Al composition 0.1 can be used. As the number of stacked layers increases, the reflectance increases. Accordingly, a larger number of layers can be stacked. For example, 10 or more pairs can be stacked.

Next, the cathode layer 6, the gate layer 8, the gate layer 10, and the anode layer 12 are stacked to form the thyristor 30. As the semiconductor layers, for example, a p-type or n-type GaAs-based material or an AlGaAs-based material can be used. Each semiconductor layer is required to have a thickness large enough to operate as the thyristor 30. An extremely large thickness of each semiconductor layer leads to an increase in the resistance in the stacking direction and an increase in production costs. Therefore, it is not favorable for each semiconductor layer to have an extremely large thickness. Accordingly, as the thickness of each semiconductor layer, the cathode layer 6 can have a thickness in a range from 300 nm to 900 nm, the gate layer 8 can have a thickness in a range from 350 nm to 1050 nm, the gate layer 10 can have a thickness in a range from 175 nm to 525 nm, and the anode layer 12 can have a thickness in a range from 160 nm to 480 nm. The entire thickness of the thyristor 30 can be set in a range from 1000 nm to 3000 nm.

After formation of the thyristor 30, the contact layer 14 is formed. As the contact layer 14, a semiconductor layer having the same conductivity type as the conductivity type of the anode layer 12 in the uppermost layer of the thyristor 30 is used. Accordingly, when p-type semiconductor is used as the anode layer 12, the contact layer 14 is also p-type semiconductor. The contact layer 14 forms a tunnel junction with the transparent electrode 18 formed on the contact layer 14. For this reason, the impurity concentration of the contact layer 14 can be increased to a level as high as possible, as long as the crystallinity is not impaired. For example, the impurity concentration can be set in a range from 1.5×10¹⁹/cm³ to 2.0×10²⁰/cm³.

As the growth method for the layers from the cathode layer 6 to the contact layer 14, general semiconductor growth methods can be used, like the buffer layer 2. However, in terms of the quality of crystal, the layers from the buffer layer 2 to the contact layer 14 can be continuously formed in the same growth apparatus. FIG. 2A illustrates a state where the layers up to the contact layer 14 are formed.

Next, by general semiconductor processes, the contact layer 14 is etched into a desired shape as illustrated in FIG. 2B. Further, the anode layer 12 is formed into a desired shape as illustrated in FIG. 2C, and the gate layers 10 and 8 are etched to thereby form a device isolation groove 24. The order of etching of the contact layer 14, the anode layer 12, the gate layers 10 and 8, and the device isolation groove 24 is merely an example, and the etching order can be changed to one suitable for processes and the like.

Next, the insulating layer 16 is formed over the entire surface as illustrated in FIG. 2D, and the insulating layer on an upper portion of the contact layer 14 and on a region in which the gate electrode 28 is formed is removed. As the insulating layer 16, SiOₓ, SiN, or the like can be formed by a sputtering method, a CVD method, or the like. Next, as illustrated in FIG. 2E, the gate electrode 28 is formed by a lift-off method or the like, and then the transparent electrode 18 is formed. As the transparent electrode 18, ITO, which is n-type oxide conductor, can be used. The transparent electrode 18 is formed by a sputtering method, a vacuum evaporation method, a spray method, or the like, and is formed into a desired shape. Further, the transparent electrode 18 is formed by a vacuum evaporation method so that the optical length in the thickness direction thereof is 0.9 to 1.1 times an odd multiple of ¼ of the light emitting wavelength λ of each light emitting thyristor 22, so that the reflection on an air interface can be reduced and the light extraction efficiency can be improved.

Next, as illustrated in FIG. 2F, the drive electrode 20 is formed, and a back surface electrode 26 is finally formed on the back surface of the substrate 1. As the drive electrode 20, a stacked body of Cr and Au can be used. The drive electrode 20 may be patterned by sequentially performing vapor deposition by a lift-off method or the like. The above-described material, film formation method, etching method, process order, and the like are not limited to those described above. Any material, film formation method, etching method, process order, and the like can be suitably selected without departing from the gist of the present invention.

In the light-emitting element array according to the present exemplary embodiment, the contact layer 14 is formed into a desired shape by a photolithography method, which is a general method for semiconductor processing, and the current constriction region is defined by the contact region between the contact layer 14 and the anode layer 12. Accordingly, the shape of the contact layer 14 and the positional relationship between the mesa structure and the side surface can be accurately obtained.

### Second Exemplary Embodiment

According to a second exemplary embodiment of the present invention, at least one of the semiconductor layers included in the semiconductor stacked structure of the thyristor 30 includes a first region and a second region having a resistance value higher than the resistance value of the first region within a plane viewed along the stacking direction, and the current constriction region is defined by the first region. Components other than the components described above are basically similar to those of the first exemplary embodiment. Accordingly, only the components different from those of the first exemplary embodiment will be described below.

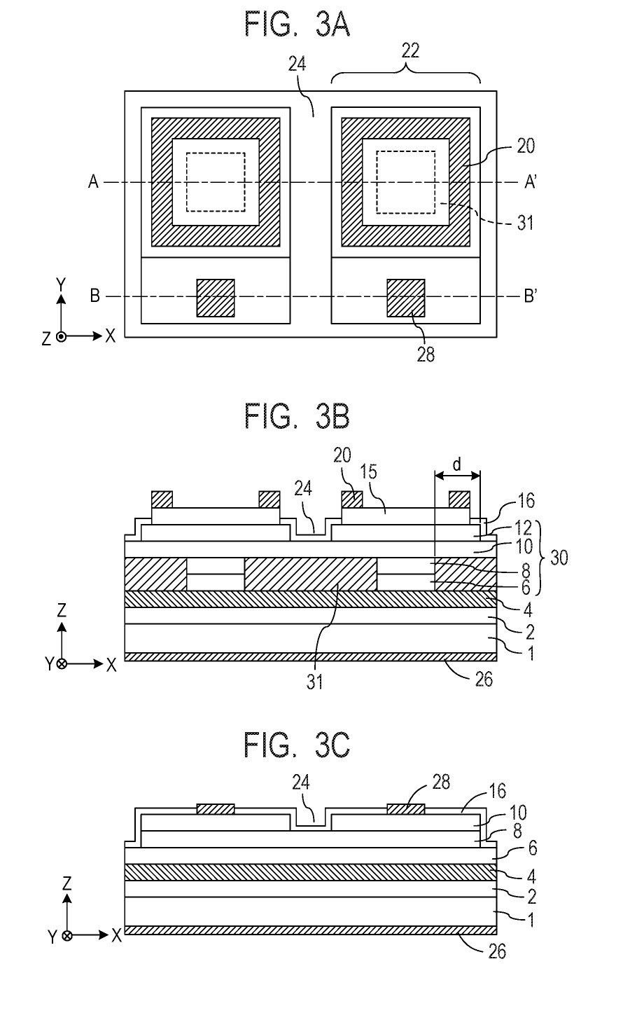

FIGS. 3A to 3C schematically illustrate the configuration according to the present exemplary embodiment, and illustrate two light emitting thyristors 22. FIG. 3A is plan view, and FIG. 3B is an end view taken along the line A-A′ in FIG. 3A, and illustrates a sectional structure of an anode portion of each of the light emitting thyristors 22. FIG. 3C is an end view taken along the line B-B′ in FIG. 3A, and illustrates a sectional structure of a gate portion of each of the light emitting thyristors 22. The same members as those illustrated in FIGS. 1A to 1C are denoted by the same reference numerals, and the descriptions thereof are omitted.

As illustrated in FIG. 3A, also in the present exemplary embodiment, the light emitting thyristors 22 each include the drive electrode 20 and the gate electrode 28 as the anode electrode on the mesa structure, and also include the current constriction region in the opening of the drive electrode 20. As illustrated in FIGS. 3A and 3B, in the present exemplary embodiment, a second region 31 in which a resistance is increased by ion implantation is formed in each of the cathode layer 6 and the gate layer 8. As a result, the cathode layer 6 and the gate layer 8 which are surrounded by the second region 31 and which have a lower resistance serve as a first region corresponding to the current constriction region. In the present invention, the second region 31 can have an electric resistance value that is 1000000 times or more the electric resistance value of the first region which is an ion-non-injection region. Proton is used as ions to be injected into the second region 31. However, the type of ions is not limited to this, and oxygen ions or boron ions can also be used.

In the present exemplary embodiment, instead of the contact layer 14 according to the first exemplary embodiment, a current diffusion layer 15 is disposed on the thyristor 30. The current diffusion layer 15 has an impurity concentration higher than the impurity concentration of the anode layer 12, and has a resistance lower than the resistance of the anode layer 12. Further, the current diffusion layer 15 enables the current to be uniformly diffused in an in-plane direction. The drive electrode 20 is formed on the current diffusion layer 15. The drive electrode 20 includes an opening, and the first region is included in the opening as viewed along the stacking direction (Z-direction).

In the light emitting thyristors 22 having the configuration as described above, the current injected in the drive electrode 20 extends in the X-direction and the Y-direction within the current diffusion layer 15 and is then injected into the thyristor 30. In the thyristor 30, the current flows only to the first region with a low resistance.

Also, in the present exemplary embodiment, the side surface distance d is greater than or equal to 4 μm. In the present exemplary embodiment, since the current constriction region corresponds to the first region, as illustrated in FIG. 3B, the distance parallel to the X-direction from an end of the first region to an end of the anode layer 12 as viewed along the stacking direction (Z-direction) of the semiconductor layers corresponds to the side surface distance d.

In the present exemplary embodiment, the second region 31 is formed in each of the cathode layer 6 and the gate layer 8. However, in the present invention, the second region 31 may be formed in at least one of the semiconductor layers constituting the thyristor 30. Further, in the present exemplary embodiment, the mesa structure includes only the anode layer 12. Like in the first exemplary embodiment, also in the present exemplary embodiment, the mesa structure may include the gate layer 10 and the gate layer 8.

(Self-Scanning-Type Light Emitting Circuit)

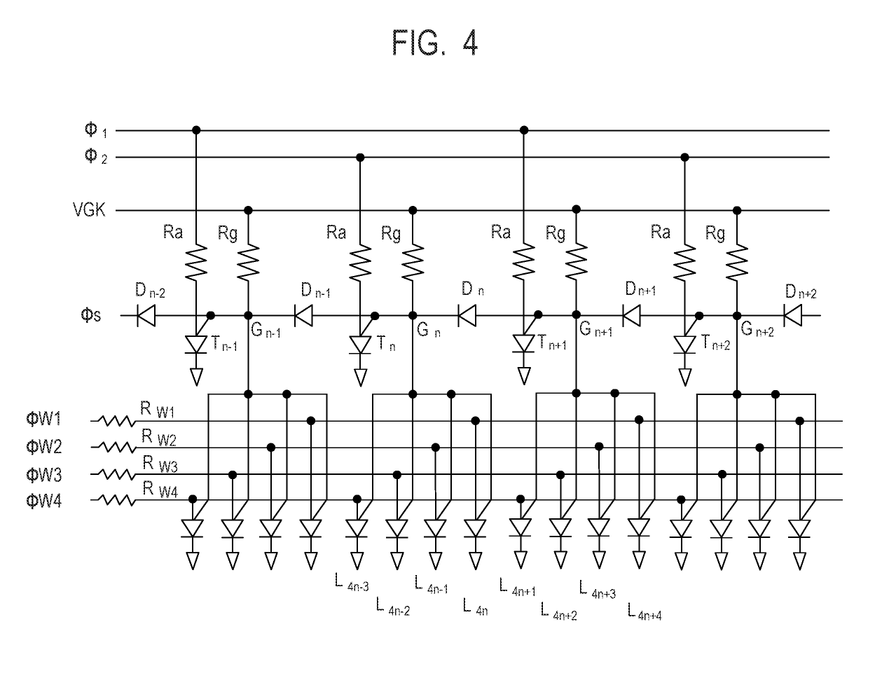

FIG. 4 is a schematic diagram illustrating a part of an equivalent circuit of a self-scanning-type light emitting circuit of the light-emitting element array according to the present invention. In FIG. 4, a suffix such as n−1 or n is added to the reference numeral denoting each component. However, in the following description, the suffix added to each reference numeral denoting the same component may be omitted. The suffix “n” is an integer greater than or equal to 2.

The light-emitting element array according to the present exemplary embodiment includes a plurality of anode resistors Ra, a plurality of gate resistors Rg, a plurality of shift thyristors T, a plurality of transfer diodes D, and a plurality of light emitting thyristors L (light emitting thyristors 22). The light-emitting element array according to the present exemplary embodiment also includes common gates Gₙ of the plurality of shift thyristors T and the light emitting thyristors L connected to the shift thyristors T.

The light-emitting element array also includes a transfer line ti for the odd-numbered shift thyristors, a transfer line Φ₂ for the even-numbered shift thyristors, turning-on signal lines ΦW1 to ΦW4 for the light emitting thyristors L, a gate line (VGK), and a start pulse line Φs. The turning-on signal lines ΦW1 to ΦW4 includes resistors R_{W1} to R_{W4}, respectively. As illustrated in FIG. 4, four light emitting thyristors L₄ₙ₋₃ to L₄ₙ are connected to one shift thyristor Tₙ, the four light-emitting elements can be turned on simultaneously.

An operation of an equivalent circuit illustrated in FIG. 4 will now be described. In the following description, assume that a voltage of 5 V is applied to the gate line VGK, and a voltage of 5 V is also supplied to each of the transfer lines Φ₁ and Φ₂ and the turning-on signal lines ΦW1 to ΦW4.

When the shift thyristor Tₙ is in an ON state, the potential of the common gate Gₙ of the light emitting thyristors L₄ₙ₋₃ to L₄ₙ connected to the shift thyristor Tₙ and the shift thyristor Tₙ is decreased to about 0.2 V. The common gate Gₙ and the common gate Gₙ₊₁ are connected with a coupling diode Dₙ, so that a potential difference substantially equal to the diffusion potential of the coupling diode Dₙ occurs.

In the present exemplary embodiment, the diffusion potential of the coupling diode Dₙ is about 1.5 V. Accordingly, the potential of the common gate Gₙ₊₁ is 1.7 V, which is the sum of the diffusion potential of 1.5 V and the potential 0.2 V of the common gate Gₙ. Similarly, the potential of the common gate Gₙ₊₂ is 3.2 V, and the potential of the common gate Gₙ₊₃ is 4.7 V. However, since the potential of the gate line VGK is 5 V, the potential of each common gate G is lower than 5 V. Accordingly, the potential of the common gate Gₙ₊₄ and subsequent common gates is 5 V. As for the common gates preceding to the common gate Gₙ (on the left side of FIG. 4), the voltage of the gate line VGK is directly applied to the common gates because the coupling diode has a reverse bias, and thus the potential of the common gates is 5 V.

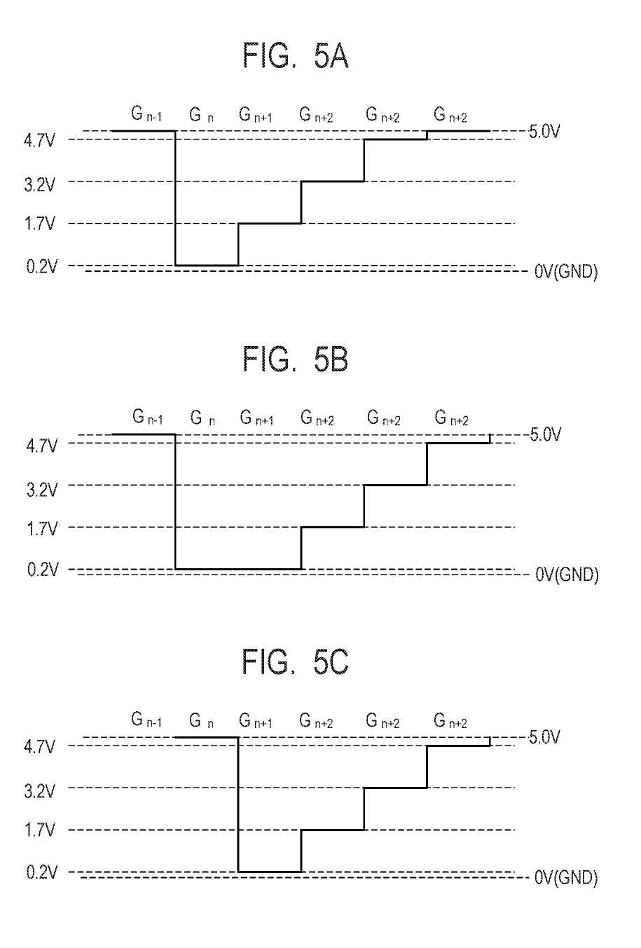

FIG. 5A illustrates a distribution of gate potentials when the shift thyristor Tₙ is in the ON state. A voltage required to turn on each shift thyristor T (the voltage is hereinafter referred to as a “threshold voltage”) is substantially equal to a voltage obtained by adding a diffusion potential to each gate potential. When the shift thyristor Tn is turned on, the shift thyristor Tₙ₊₂ has a lowest gate potential among the shift thyristors connected to the same transfer line Φ₁. Since the potential of the gate Gₙ₊₂ of the shift thyristor Tₙ₊₂ is 3.2 V as described above, a threshold voltage of the shift thyristor Tₙ₊₂ is 4.7 V.

However, since the shift thyristor Tₙ is turned on, the potential of the transfer line Φ₁ is drawn into about 1.5 V (diffusion potential), which is lower than the threshold voltage of the shift thyristor Tₙ₊₂, and thus the shift thyristor Tₙ₊₂ cannot be turned on. The threshold voltage of other shift thyristors connected to the same transfer line Φ₁ is higher than the threshold voltage of the shift thyristor Tₙ₊₂, and thus the shift thyristor Tₙ₊₂ cannot be turned on. Accordingly, only the shift thyristor Tₙ can be maintained in the ON state.

As for the shift thyristors connected to the transfer line Φ₂, the threshold voltage of the shift thyristor Tₙ₊₁ having a lowest threshold voltage is 3.2 V, and the threshold voltage of the shift thyristor Tₙ₊₃ having a second lowest threshold voltage is 6.2 V. When 5 V is supplied to the transfer line Φ₂ in this state, only the shift thyristor Tₙ₊₁ can be shifted to the ON state. In this state, the shift thyristors Tₙ and Tₙ₊₁ are turned on simultaneously, and the gate potential of each shift thyristor located on the right side of the shift thyristor Tₙ₊₁ is decreased by the diffusion potential. However, since the voltage of the gate line VGK is 5 V and the gate voltage is limited by the gate line VGK, the gate voltage of the shift thyristors located on the right side of the shift thyristor Tₙ₊₅ is 5 V. FIG. 5B illustrates a distribution of gate voltages in this case.

When the potential of the transfer line Φ₁ is decreased to 0 V in this state, the shift thyristor Tₙ is turned off, and the potential of the gate Gₙ increases to the potential of the gate line VGK. FIG. 5C illustrates a distribution of gate voltages in this case. Thus, the transfer of the ON state from the shift thyristor Tₙ to the shift thyristor Tₙ₊₁ is completed.

Next, a light emitting operation of each light emitting thyristor L will be described. When only the shift thyristor Tₙ is in the ON state, the four light emitting thyristors L4ₙ₋₃ to L₄ₙ are commonly connected to the gate Gₙ of the shift thyristor Tₙ, and the gate potential of each of the light emitting thyristors L₄ₙ₋₃ to L₄ₙ is 0.2 V, which is equal to the potential of the gate Gₙ. Accordingly, the threshold voltage of each light emitting thyristor L is 1.7 V, and each light emitting thyristor can be turned on when a voltage of 1.7 V or higher is supplied from the turning-on signal lines ΦW1 to ΦW4. Therefore, when the shift thyristor Tₙ is in the ON state, a turning-on signal is supplied to the turning-on signal lines ΦW1 to ΦW4, thereby enabling all combinations of the four light emitting thyristors L₄ₙ₋₃ to L₄ₙ to selectively emit light. Specifically, the light emitting thyristors L₄ₙ₋₃ to L₄ₙ can be selected by the corresponding shift thyristor Tₙ and thus can emit light. In this case, the potential of the gate Gₙ₊₁ of the shift thyristor Tₙ₊₁ adjacent to the shift thyristor Tₙ is 1.7 V, and a threshold for each of the light emitting thyristors L₄ₙ₊₁ to L₄ₙ₊₄ commonly connected to the gate Gₙ₊₁ is 3.2 V.

The turning-on signal supplied from the turning-on signal lines ΦW1 to ΦW4 is 5 V, and the light emitting thyristors L₄ₙ₊₁ to L₄ₙ₊₄ can be almost turned on in the same lighting pattern as the lighting pattern of the light emitting thyristors L₄ₙ₋₃ to L₄ₙ. However, a threshold V of each of the light emitting thyristors L₄ₙ₋₃ to L₄ₙ is low. Accordingly, when the turning-on signal is supplied, the light emitting thyristors L₄ₙ₋₃ to L₄ₙ can be turned on earlier than the light emitting thyristors L₄ₙ₊₁ to L₄ₙ₊₄. Once the light emitting thyristors L₄ₙ₋₃ to L₄ₙ are turned, the potential of the connected turning-on signal lines ΦW1 to ΦW4 is drawn into about 1.5 V (diffusion potential) and thus becomes lower than the threshold voltage of each of the light emitting thyristors L₄ₙ₊₁ to L₄ₙ₊₄. Therefore, the light emitting thyristors L₄ₙ₊₁ to L₄ₙ₊₄ cannot be turned on. In this manner, a plurality of light emitting thyristors L is connected to one shift thyristor T, thereby enabling the plurality of light emitting thyristors L to be turned on simultaneously.

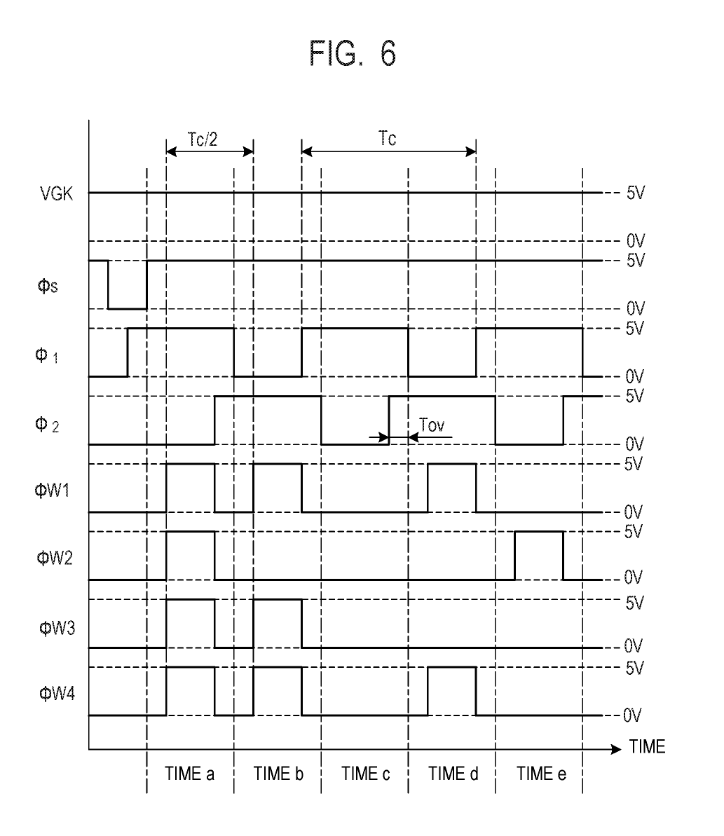

FIG. 6 illustrates an example of a drive signal waveform. The gate line VGK is constantly supplied with a voltage of 5 V. A clock signal Φ₁ for the odd-numbered shift thyristors and a clock signal Φ₂ for the even-numbered shift thyristors are applied in the same period Tc, and a signal Φ_{S} for start is supplied with a voltage of 5 V. However, the clock signal Φ₁ is decreased to 0 V before the clock signal Φ₁ first reaches 5 V so that a potential difference is provided to the gate line. Thus, the potential of the gate of the first shift thyristor is drawn into 1.7 V from 5 V and the threshold voltage is 3.2 V, so that the shift thyristor can be turned on by the clock signal Φ₁. When a voltage of 5 V is applied to the clock signal Φ₁, a voltage of 5 V is supplied to the signal Φ_{S} with a delay after the first shift thyristor T shifts to the ON state, and then a voltage of 5 V is continuously supplied to the signal Φ_{S}. The clock signals Φ₁ and Φ₂ are configured so as to have a time T_{OV} at which the ON states (5 V in this case) of the clock signals overlap each other and have a substantially complementary relationship. The signals ΦW1 to ΦW4 for turning on the light emitting thyristors are transmitted in a period that is half the period of the clock signals Φ₁ and Φ₂, and the corresponding shift thyristor T is turned on when a voltage of 5 V is applied during the ON state. For example, at a time “a”, all the four light emitting thyristors L connected to the same shift thyristor T are turned on, and at a time “b”, all the three light emitting thyristors L are turned on simultaneously. At a time “c”, all the light emitting thyristors L are turned off, and at a time “d”, two light emitting thyristors L are turned on simultaneously. At a time “e”, one light emitting thyristor L is turned on.

In the present exemplary embodiment, four light emitting thyristors L are connected to one shift thyristor T. However, the number of light emitting thyristors connected to one shift thyristor T is not limited to four. Less than four or more than four light emitting thyristors may be connected to one shift thyristor T depending on the intended use. Although the circuit in which the cathode of each thyristor is commonly used has been described above, a circuit in which the anode of each thyristor is commonly used can also be applied by inverting the polarity as needed.

(Light Exposure Head)

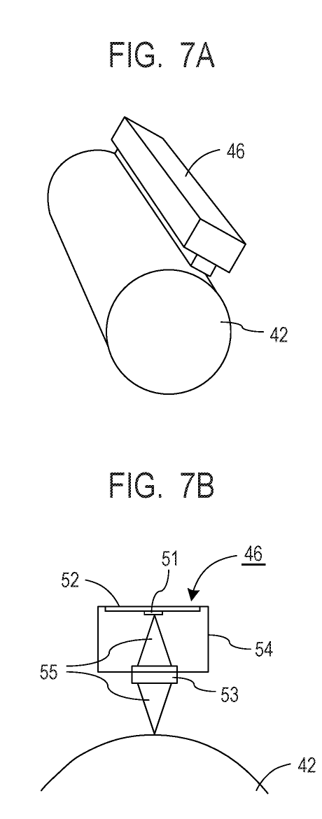

The light exposure head according to the present invention includes at least the above-described light-emitting element array according to the present invention, and the optical system member that collects light emitted from the light-emitting element array. The light exposure head according to the present invention will be described with reference to FIGS. 7A and 7B. FIGS. 7A and 7B illustrate the layout of the light exposure head and the photosensitive drum according to the present invention. FIG. 7A is a perspective view, and FIG. 7B is a schematic sectional view.

A light exposure head 46 according to the present invention exposes a surface of a photosensitive drum 42 to light, and the light exposure head 46 can be suitably used when an electrostatic latent image is formed on the photosensitive drum 42. However, the application of the light exposure head 46 is not particularly limited. For example, the light exposure head 46 can also be used as a light source for a line scanner.

The light exposure head 46 includes a light-emitting element group 51 including a plurality of light-emitting element arrays, a printed circuit board 52 on which the light-emitting element group 51 is mounted, a rod lens array 53, and a housing (support member) 54 that supports the rod lens array 53 and the printed circuit board 52. Each of the plurality of light-emitting element arrays included in the light-emitting element group 51 is the light-emitting element array according to the present invention. A plurality of light-emitting element arrays may be provided in a direction perpendicular to the array of light-emitting elements in the light-emitting element array. In the light-emitting element group 51, a plurality of light-emitting elements may be two-dimensionally disposed in a plurality of columns and a plurality of rows. The rod lens array 53 is an optical system member that collects light from the light-emitting element group 51.

The light exposure head 46 according to the present exemplary embodiment collects light from the light-emitting element group 51 through the rod lens array 53. The photosensitive drum 42 is irradiated with the light collected by the rod lens array 53.

FIGS. 7A and 7B each illustrate the layout of the photosensitive drum 42 and the light exposure head 46 and the state where light from the light exposure head is focused on the surface of the photosensitive drum 42. The light exposure head 46 is disposed so as to face the photosensitive drum 42. Each of the light exposure head 46 and the photosensitive drum 42 is used by being mounted on the image forming apparatus with a mounting member (not illustrated). FIG. 7B illustrates a light beam 55.

Assembly and adjustment operations for each light exposure head 46 can be performed in a factory, and focus adjustment and light amount adjustment at each spot can be performed so that a light focusing position can be appropriately set when the light exposure head 46 is mounted on the image forming apparatus. In this case, a predetermined interval is set as the distance between the photosensitive drum 42 and the rod lens array 53 and the distance between the rod lens array 53 and the light-emitting element group 51. Thus, the light from the light exposure head 46 is focused on the photosensitive drum 42. Accordingly, during the focus adjustment, the mounting position of the rod lens array 53 is adjusted so that the distance between the rod lens array 53 and the light-emitting element group 51 is set to a desired value. Further, during the light amount adjustment, the light-emitting elements are caused to sequentially emit light, and the drive current for each light-emitting element is adjusted so that a predetermined amount of light is collected through the rod lens array 53.

The light exposure head according to the present invention uses the light-emitting element array according to the present invention. Consequently, the light exposure head having a higher contrast than that in the related art and having less variation can be obtained.

(Image Forming Apparatus)

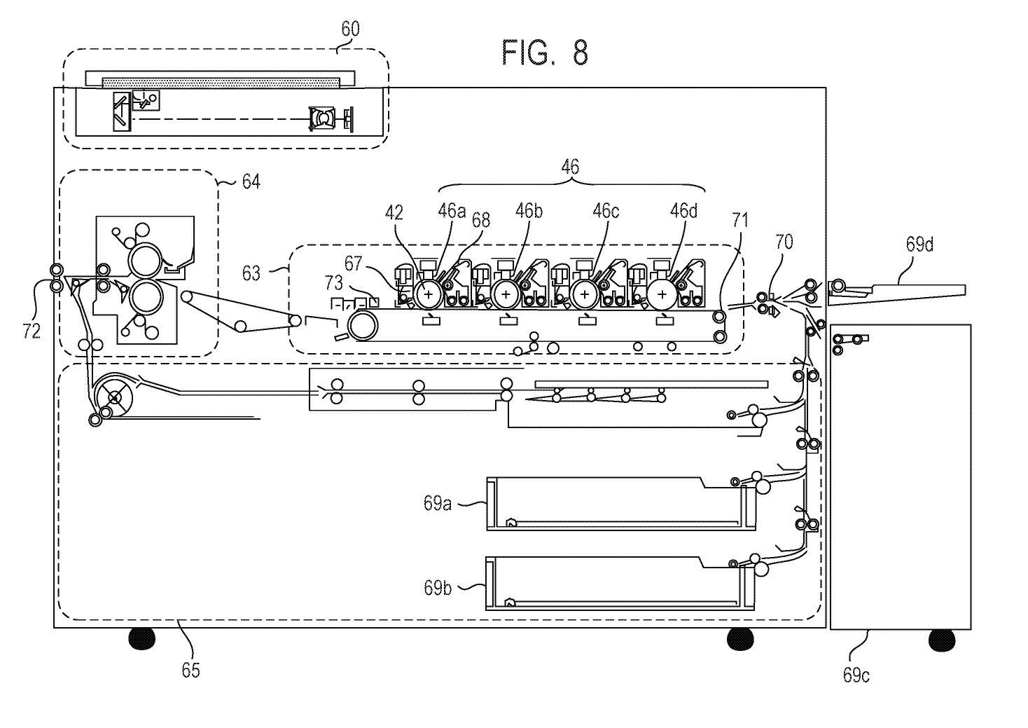

The image forming apparatus according to the present invention includes an image supporting body, a charging unit that charges the surface of the image supporting body, a light exposure head according to the present invention that forms an electrostatic latent image on the surface of the image supporting body, a development unit that develops the electrostatic latent image, and a transfer unit that transfers the developed image onto a recording medium. The image forming apparatus according to the present invention will be described with reference to FIG. 8. FIG. 8 is a sectional view schematically illustrating the configuration of the image forming apparatus according to an exemplary embodiment of the present invention.

The image forming apparatus according to the present exemplary embodiment is an electrophotographic image forming apparatus, and includes a scanner unit 60, an image forming unit 63, a fixing unit 64, a sheet feeding/conveyance unit 65, and a control unit (not illustrated) that controls these units.

The scanner unit 60 illuminates a document to be read, and optically scans an image on the document. The image scanned by the scanner unit 60 is converted into an electric signal, thereby creating image data.

The image forming unit 63 includes a plurality of development units that performs development by electrophotographic processes. Each development unit includes a photosensitive drum 42, a light exposure head 46, a charger 67, and a developing device 68. Each development unit may be a process cartridge in which components used for development of a toner image are accommodated. In this case, the process cartridge can be detachably mounted on the main body of the image forming apparatus.

The photosensitive drum 42 is an image supporting body on which an electrostatic latent image is formed. The photosensitive drum 42 is rotationally driven and is charged by the charger 67.

The light exposure head 46 is the light exposure head according to the present invention. The light exposure head 46 irradiates the photosensitive drum 42 with light corresponding to image data, and forms an electrostatic latent image on the photosensitive drum 42. Specifically, as illustrated in FIGS. 7A and 7B, the light exposure head 46 causes the rod lens array 53 to collect light generated from chip surfaces arranged in the light-emitting element group 51 on the photosensitive drum 42, and forms the electrostatic latent image corresponding to the image data on the photosensitive drum 42.

The developing device 68 supplies toner (developer) to the electrostatic latent image formed on the photosensitive drum 42 and develops a toner image. The toner is stored in a storage unit. The storage unit storing the toner can be included in each development unit. The developed toner image (developer image) is transferred onto a recording medium, such as paper, which is conveyed onto a transfer belt 71.

The image forming apparatus according to the present exemplary embodiment includes four development units (development stations) that perform development by a series of electrophotographic processes. The toner image from each development unit is transferred to form a desired image. The four development units contain toner of different colors, respectively. Image forming operations for magenta, yellow, and black are sequentially executed after a lapse of a predetermined time from the start of image formation for cyan.

The sheet feeding/conveyance unit 65 feeds a sheet from a predetermined sheet feeding unit out of sheet feeding units 69a and 69b in the main body, an external sheet feeding unit 69c, and a manual feed sheet feeding unit 69d, and the fed sheet is conveyed to registration rollers 70.

The registration rollers 70 convey the sheet onto the transfer belt 71 so that the toner image formed by the image forming unit 63 described above is transferred onto the sheet.

An optical sensor 73 is disposed so as to face the surface of the transfer belt 71 on which the toner image is transferred. To derive the amount of color deviation between the development units, position detection on a test chart printed on the transfer belt 71 is carried out. The derived amount of color deviation is sent to an image controller unit (not illustrated) and is used for correction of image positions in each color. This control processing enables a full-color toner image with no color deviation to be transferred onto a sheet.

The fixing unit 64 incorporates a plurality of rollers and a heat source such as halogen heater. The fixing unit 64 dissolves and fixes, by heat and pressure, the toner on the sheet on which the toner image is transferred from the surface of the transfer belt 71, and discharge rollers 72 discharge the sheet to the outside of the image forming apparatus.

An image formation control unit (not illustrated) is connected to a multifunction peripheral (MFP) control unit that controls the entire MFP including the image forming apparatus, and executes control processing in response to an instruction from the MFP control unit. Further, the image formation control unit sends an instruction to each of the scanner unit 60, the image forming unit 63, the fixing unit 64, and the sheet feeding/conveyance unit 65 so that these units can smoothly operate in harmony with each other, while managing the states of these units.

When image formation is performed using the light-emitting element array according to the present invention as the light exposure head, the length of the light-emitting element array in the light exposure head is determined depending on the width of the image region on the photosensitive drum, and the pitch between the light-emitting elements (density of light emitting points) is determined depending on the resolution. For example, in the case of forming an image with a resolution of 1200 dpi, the interval between the centers of the adjacent light emitting thyristors 22 among the plurality of light emitting thyristors 22 separated by the device isolation groove 24 is set to about 21.16 μm.

The number of components to be used in the image forming apparatus using the light exposure head as described above is less than the number of components used in a laser scanning type image forming apparatus in which a laser beam is deflected and scanned by a polygon motor. Accordingly, in the image forming apparatus using the light exposure head, the miniaturization of the apparatus and a reduction in costs can be achieved easily.

The image forming apparatus according to the present exemplary embodiment uses the light exposure head including the light-emitting element array in which the light emission from components other than the light emitting thyristors 22 each serving as the light-emitting element can be reduced as compared with the related art. Consequently, the use of the light exposure head having a higher contrast than that in the related art makes it possible to obtain the image forming apparatus that forms an image with a high quality.

### EXAMPLES

The light-emitting element array according to the first exemplary embodiment illustrated in FIGS. 1A to 1C was prepared, and the light emitting output at the side surface distance d and variations in light emission were examined.

On the n-type GaAs substrate 1, the buffer layer 2 made of n-type GaAs was epitaxially grown. Next, as the DBR layer 4, 20 pairs of n-type high-Al-composition AlGaAs and low-Al-composition AlGaAs were alternately stacked so that the optical length of each layer was set to ¼ of the light emitting wavelength λ of the light emitting thyristor 30. Next, n-type AlGaAs having an Al composition of 25% and an impurity concentration of 2×10¹⁸/cm³ was stacked with a thickness of 600 nm as the cathode layer 6, and p-type AlGaAs having an Al composition of 15% and an impurity concentration of 3×10¹⁷/cm³ was stacked with a thickness of 700 nm as the p-type gate layer 8. Next, n-type AlGaAs having an Al composition of 15% and an impurity concentration of 3×10¹⁸/cm³ was stacked with a thickness of 350 nm as the n-type gate layer 10, and p-type AlGaAs having an Al composition of 30% and an impurity concentration of 2×10¹⁷/cm³ was stacked with a thickness of 320 nm as the anode layer 12. Thus, the thyristor 30 was obtained.

On the thyristor 30, p-type AlGaAs having an Al composition of 30% and an impurity concentration of 7×10¹⁹/cm³ was further formed with a thickness of 200 nm as the contact layer 14. The layers from the buffer layer 2 to the contact layer 14 were continuously stacked in the same growth apparatus.

Next, by general semiconductor processes, the contact layer 14 was formed and the anode layer 12 was formed into a desired shape. Further, the gate layers 10 and 8 were etched to form the device isolation groove 24.

Next, the insulating layer 16 was formed over the entire surface, and the insulating layer 17 in the upper portion of the contact layer 14 and in the region of the gate electrode 28 was removed. Next, the gate electrode 28 was formed by the lift-off method, and ITO was deposited as the transparent electrode 18 by the vacuum evaporation method and was formed into a desired shape. In this example, the optical length of the ITO in the thickness direction (Z-direction) was set to be ¼ of the light emitting wavelength λ of the light emitting thyristor 30, thereby reducing the reflection on the air interface and improving the light extraction efficiency.

Next, Cr and Au were sequentially deposited in vacuum as the drive electrode 20, and the drive electrode 20 was formed into a desired shape by the lift-off method. Lastly, AuGe/Ni/Au were sequentially deposited in vacuum on the back surface of the substrate 1 as the back surface electrode 26, and a heat treatment was performed on the back surface electrode 26.

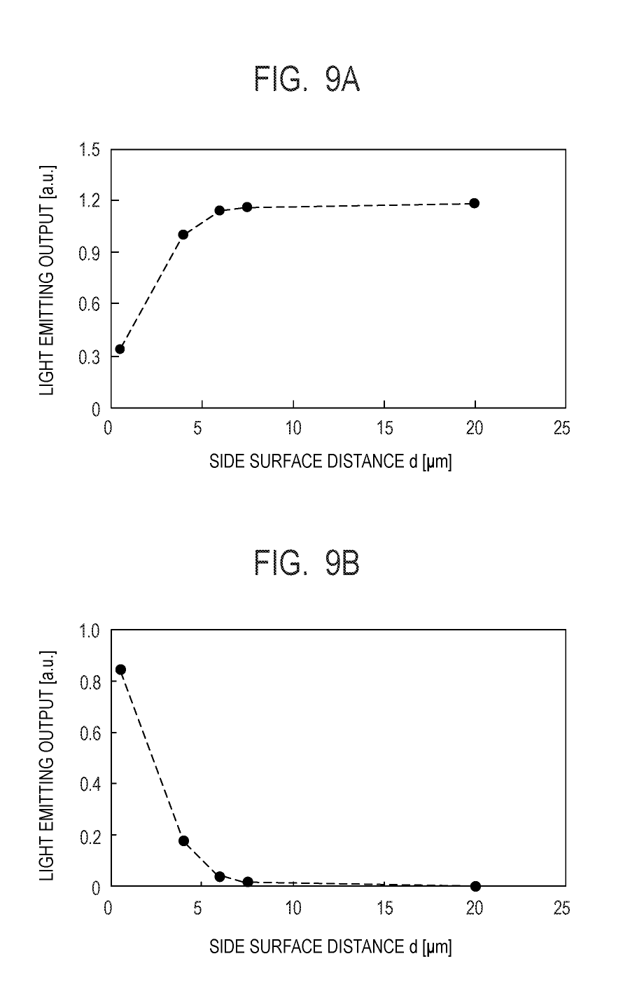

In this example, the side surface distance d was changed in various ways, and the relationship between the light emitting loss and the side surface distance d was examined. FIG. 9A illustrates the results. As illustrated in FIG. 9A, the light output was substantially saturated at the side surface distance d of 20 μm. Accordingly, the relationship between the light emitting loss and the side surface distance d was obtained assuming that the loss at the side surface distance d of 20 μm was 0. FIG. 9B illustrates the results. As seen from FIG. 9B, when the side surface distance d was set to be less than or equal to 4 μm, the loss increased sharply. On the other hand, it is less likely that the effect of reducing the loss can be obtained even when the side surface distance d is set to greater than or equal to 20 μm.

Further, in this example, the light-emitting element array having a density of 1200 dpi and a pitch of 21.16 μm between the light emitting thyristors 22 disposed in the column direction was prepared. Samples in which the contact layer 14 was disposed at the center of the mesa structure in the column direction and the side surface distance d was set to 3 μm, 4 μm, 6 μm, and 7.5 μm were formed. Table 1 illustrates results of comparison between light emitting outputs using the same current. In the case where the density of the light emitting thyristors 22 was 1200 dpi, when the side surface distance d was set to be greater than or equal to 7.5 μm, the width of the contact layer 14 was less than or equal to 3 μm, which is not favorable in terms of the current density. Accordingly, the upper limit of the side surface distance d was set to 7.5 μm. Table 1 illustrates the light output of each of the samples having the side surface distance d in the case where the light emitting output when the side surface distance d is 4 μm is “1”.

TABLE 1

| Side surface distance d [μm] | Light-emitting amount ratio |
|---|---|
| 3 | 67% |
| 4 | 100% |
| 6 | 114% |
| 7.5 | 116% |

As illustrated in Table 1, when the side surface distance d increases from 6 μm to 7.5 μm, the light emitting output increases by 2%. In other words, this indicates that when the side surface distance d is in a range from 6 μm to 7.5 μm, the light emitting output has a variation of 2%. When the side surface distance d is in a range from 6 μm to 4 μm, the light emitting output decreases by 14%, and when the side surface distance d is in a range from 4 μm to 3 μm, the light emitting output decreases by 67%. The variation in the side surface distance d is now considered. The side surface distance d is a distance from a side surface of the mesa structure to an end of the contact layer 14, and the side surface distance d can be set with the precision of general photolithography processes. Accordingly, a precision of ±0.5 μm can be obtained. The variation in the light emitting output at the side surface distance d in the range from 6 μm to 7.5 μm is 2%. In terms of proportional calculation, the variation in the light emitting output per 0.5 μm in this region is about 0.4%. Accordingly, it is considered that, in the region having the side surface distance d in the range from 6 μm to 7.5 μm, the variation in the light emitting output due to process variations is about ±0.4%. Similarly, in the range having the side surface distance d in a range from 4 μm to 6 μm, the variation in the light emitting output due to process variations is 3.5%, and in the range having the side surface distance d in a range from 3 μm to 4 μm, the variation in the light emitting output is 16.5%. As described above, it is obvious that the side surface distance d is set to be greater than or equal to 4 μm, thereby increasing the light emitting output and reducing the variation in the light emitting output due to process variations to 5% or less.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-231541, filed Dec. 1, 2017, which is hereby incorporated by reference herein in its entirety.

What is claimed is:

1. A light-emitting element array comprising:
a substrate; and
a plurality of light emitting thyristors disposed in an array on the substrate, wherein
the light emitting thyristors each have a semiconductor stacked structure in which a first semiconductor layer having a first conductivity type, a second semiconductor layer having a second conductivity type different from the first conductivity type, a third semiconductor layer having the first conductivity type, and a fourth semiconductor layer having the second conductivity type are stacked in this order from a substrate side,
at least a part of the semiconductor stacked structure constitutes a mesa structure,
the light emitting thyristors each include a current constriction region, and
a minimum distance d between a side surface of the mesa structure and the current constriction region in a direction in which the plurality of light emitting thyristors is disposed is greater than or equal to 4 μm as viewed along a stacking direction of the plurality of semiconductor layers.

2. The light-emitting element array according to claim 1, wherein the minimum distance d is greater than or equal to 5 μm.

3. The light-emitting element array according to claim 1, wherein the minimum distance d is less than or equal to 20 μm.

4. The light-emitting element array according to claim 1, wherein the minimum distance d is less than or equal to 10 μm.

5. The light-emitting element array according to claim 1, wherein
on the semiconductor stacked structure, a contact layer in contact with the fourth semiconductor layer is formed, and
the current constriction region is defined by a region in which the fourth semiconductor layer is in contact with the contact layer.

6. The light-emitting element array according to claim 5, wherein
the light emitting thyristors each include a transparent electrode configured to cover the semiconductor stacked structure and the contact layer, and a drive electrode including an opening and formed on the transparent electrode and on a region of the semiconductor stacked structure where the contact layer is not formed, and
the contact layer is disposed in the opening as viewed along the stacking direction of the plurality of semiconductor layers.

7. The light-emitting element array according to claim 6, wherein assuming that a light emitting wavelength of each of the light emitting thyristors is represented by λ, an optical length in a thickness direction of the transparent electrode is 0.9 to 1.1 times an odd multiple of λ/4.

8. The light-emitting element array according to claim 1, wherein
at least one of the semiconductor layers included in the semiconductor stacked structure includes a first region and a second region having an electric resistance value higher than the electric resistance value of the first region within a plane viewed along the stacking direction of the plurality of semiconductor layers, and
the current constriction region is defined by the first region.

9. The light-emitting element array according to claim 8, wherein the second region is a region in which a resistance of a semiconductor layer is increased by ion implantation.

10. The light-emitting element array according to claim 8, wherein a drive electrode including an opening is formed on the semiconductor stacked structure, and the first region is disposed in the opening as viewed along the stacking direction of the plurality of semiconductor layers.

11. The light-emitting element array according to claim 1, wherein the semiconductor stacked structure has a thickness in a range from 1000 nm to 3000 nm.

12. The light-emitting element array according to claim 1, wherein the substrate is n-type semiconductor.

13. The light-emitting element array according to claim 1, wherein the semiconductor stacked structure contains one of a GaAs-based material and an AlGaAs-based material.

14. A light exposure head comprising:
the light-emitting element array according to claim 1; and
an optical system member configured to collect light emitted from the light-emitting element array.

15. An image forming apparatus comprising:
an image supporting body;
a charging unit configured to charge a surface of the image supporting body;
a light exposure head configured to expose a surface of the image supporting body to light and form an electrostatic latent image on the surface of the image supporting body, the surface of the image supporting body being charged by the charging unit;
a development unit configured to develop the electrostatic latent image formed by the light exposure head; and
a transfer unit configured to transfer the image developed by the development unit onto a recording medium,
wherein the light exposure head is the light exposure head according to claim 14.
